(19) United States
(12) Patent Application Publication
(10) Pub. No.: US 2023/0061927 A1
(43) Pub. Date: Mar. 2, 2023

(54) TEMPERATURE CONTROL APPARATUS AND TEMPERATURE CONTROL METHOD

(71) Applicant: CHANGXIN MEMORY TECHNOLOGIES, INC., Hefei City (CN)

(72) Inventors: Enhao CHEN, Hefei City (CN); Xing ZHANG, Hefei City (CN)

(73) Assignee: CHANGXIN MEMORY TECHNOLOGIES, INC., Hefei City (CN)

(21) Appl. No.: 17/809,154

(22) Filed: Jun. 27, 2022

Related U.S. Application Data
(63) Continuation of application No. PCT/CN2021/130574, filed on Nov. 15, 2021.

(30) Foreign Application Priority Data
Aug. 20, 2021 (CN) 202110962288.0

(51) Int. Cl. G03F 7/20; G05D 23/19

(52) U.S. Cl. CPC G03F 7/70858; G05D 23/1932; G03F 7/70483; G03F 7/7085

(57) ABSTRACT

A temperature control apparatus is located at an interface between a coating and developing machine and a lithography machine, and includes a temperature detecting device and a temperature control device. The temperature detecting device is connected to the temperature control device. The temperature detecting device is configured to detect an actual temperature at the interface in real time. The temperature control device is configured to control the actual temperature at the interface to reach a target temperature when the actual temperature is not equal to the target temperature.

### CROSS-REFERENCE TO RELATED APPLICATIONS

This is a continuation of International Patent Application No. PCT/CN2021/130574 filed on Nov. 15, 2021, which claims priority to Chinese Patent Application No. 202110962288.0 filed on Aug. 20, 2021. The disclosures of these applications are hereby incorporated by reference in their entirety.

### BACKGROUND

In the semiconductor technologies, a photolithography process is a cyclic assembly line operation including coating, exposure and development and completed at a high speed by an all-in-one machine formed by connection of a coater and a lithography machine. After coating and baking process before high-temperature exposure, a wafer first enters an interface block chill plate (iCPL) to be subjected to annealing treatment, so that the temperature of the wafer is reduced to the room temperature, and stress generated by the wafer due to a previous process is released, to recover deformation. The wafer then passes through an interface between the coater and the lithography machine and enters a temperature stable unit (TSU) of the lithography machine to be subjected to temperature control, such that alignment and exposure actions are carried out when the wafer is kept at a constant temperature, to ensure overlay and line width stability.

However, temperature control is not implemented at the interface, and wafers may enter the TSU with different temperatures at the interface. If temperature control time in the TSU is not enough, and stress of a wafer is not released in time, deformation of the wafer may affect authenticity and stability of an overlay during alignment of the lithography machine, which may even exceed product specifications, so that the wafer needs to be reworked, which reduces the production line capacity. If the temperature control time in the TSU is too long, the production capacity of the lithography machine is reduced.

### SUMMARY

The disclosure relates to the technical field of semiconductors, and relates to, but is not limited to, a temperature control apparatus and a temperature control method.

In view of the above, embodiments of the disclosure provide a temperature control apparatus and a temperature control method.

In a first aspect, the embodiments of the disclosure provide a temperature control apparatus, located at an interface between a coating and developing machine and a lithography machine, and including a temperature detecting device and a temperature control device.

The temperature detecting device is connected to the temperature control device.

The temperature detecting device is configured to detect an actual temperature at the interface in real time.

The temperature control device is configured to control the actual temperature at the interface to reach a target temperature when the actual temperature is not equal to the target temperature.

In a second aspect, the embodiments of the disclosure provide a temperature control method, applied to the temperature control apparatus above. The temperature control apparatus includes a temperature detecting device and a temperature control device. The method includes:

determining the target temperature at the interface between the coating and developing machine and the lithography machine;

acquiring, by the temperature detecting device, the actual temperature at the interface in real time; and

controlling, by the temperature control device, the actual temperature at the interface to reach the target temperature when the actual temperature is not equal to the target temperature.

### BRIEF DESCRIPTION OF THE DRAWINGS

In the drawings (which are not necessarily drawn to scale), similar reference numerals may denote similar components in different views. The similar reference numerals having different letter suffixes may denote different examples of the similar components. The drawings generally illustrate various embodiments discussed in the disclosure by way of example and not by way of limitation.

FIG. 1 is a schematic structural diagram of modules in an all-in-one coating and lithography machine in some implementations.

FIG. 2 is a first optional schematic structure diagram of a temperature control apparatus provided by embodiments of the disclosure.

FIG. 3 is a second optional schematic structure diagram of a temperature control apparatus provided by embodiments of the disclosure.

FIG. 4 is a third optional schematic structure diagram of a temperature control apparatus provided by embodiments of the disclosure.

FIG. 5 is a fourth optional schematic structure diagram of a temperature control apparatus provided by embodiments of the disclosure.

FIG. 6 is a fifth optional schematic structure diagram of a temperature control apparatus provided by embodiments of the disclosure.

FIG. 7 is a sixth optional schematic structure diagram of a temperature control apparatus provided by embodiments of the disclosure.

FIG. 8 is a seventh optional schematic structure diagram of a temperature control apparatus provided by embodiments of the disclosure.

FIG. 9 is a schematic flowchart of a temperature control method provided by embodiments of the disclosure.

FIG. 10 is an optional schematic structure diagram of a temperature control apparatus provided by embodiments of the disclosure.

### DETAILED DESCRIPTION

Exemplary implementations of the disclosure will be described in more detail below with reference to the accompanying drawings. Although the accompanying drawings illustrate the exemplary implementations of the disclosure, it should be understood that the disclosure can be implemented in various forms, and should not be limited by the particular implementations described here. On the contrary, the purpose of providing these implementations is to understand the disclosure more thoroughly, and the scope of the disclosure may be fully conveyed to those skilled in the art.

In the following description, numerous specific details are given in order to provide a more thorough understanding of the disclosure. However, it is apparent to those skilled in the art that the disclosure may be implemented without one or more of these details. In other examples, in order to avoid confusion with the disclosure, some technical features well known in the art are not described. That is, not all the features of the actual embodiments are described herein, and well-known functions and structures are not described in detail.

In the accompanying drawings, for clarity, the sizes of layers, areas, elements and their relative sizes may be exaggerated. The same reference numerals are used to identify the same components throughout the disclosure.

It should be understood that when an element or layer is referred to as being “on”, “adjacent to”, “connected to” or “coupled to” another element or layer, it can be directly on the other element or layer, adjacent, connected or coupled to the other element or layer, or, intervening elements or layers may be presented. In contrast, when an element is referred to as being “directly on”, “directly adjacent to”, “directly connected to” or “directly coupled to” another element or layer, there are no intervening elements or layers. It should be understood that although the terms “first”, “second”, “third”, etc., are used to describe the elements, components, areas, layers and/or sections, those elements, components, areas, layers and/or sections should not be limited by these terms. The terms are merely used to distinguish one element, component, area, layer or section from another element, component, area, layer or section. Thus, a first element, component, area, layer or section, which is discussed below, may be referred to as a second element, component, area, layer or section, without departing from the teaching of the disclosure. Moreover, when a second element, component, area, layer or section is discussed, it does not mean that a first element, component, area, layer or section is necessarily presented in the disclosure.

The terms used herein are for the purpose of describing specific embodiments only and are not intended to limit the disclosure. As used herein, the singular forms “a”, “an” and “the/said” are intended to include the plural forms as well, unless the context clearly indicates otherwise. It should be further understood that the terms “consisting of” and/or “include”, when used in this description, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of the associated listed items.

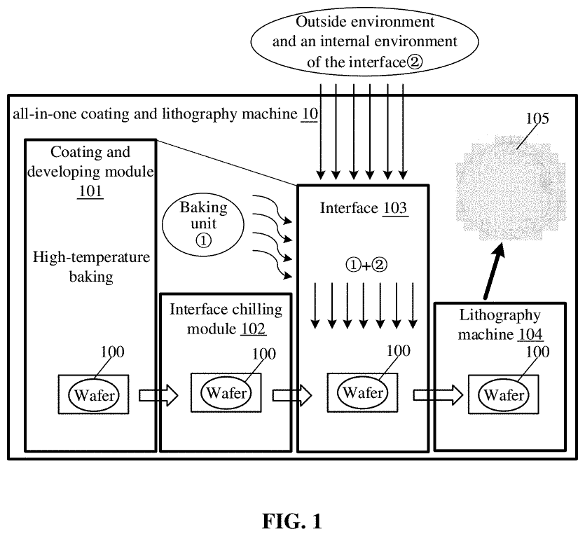

FIG. 1 is a schematic structural diagram of modules in an all-in-one coating and lithography machine in some implementations. A coating and lithography process in some implementations is illustrated with reference to FIG. 1. As illustrated in FIG. 1, an all-in-one coating and lithography machine 10 in some implementations mainly includes four modules, which are respectively a coating and developing module 101, an interface chilling module 102, an interface 103 and a lithography machine 104. A wafer 100 is subjected to a coating and baking process in the coating and developing module 101. Then, the wafer 100 enters the interface chilling module 102, to be subjected to annealing treatment, such that the temperature of the wafer is reduced to the room temperature, and stress generated by the wafer due to a previous process is released, to recover deformation. The wafer 100 then passes through the interface 103 of the all-in-one coating and lithography machine 10 and enters a temperature stable unit (TSU) of the lithography machine 104 to be subjected to temperature control, so that a pre-alignment step before exposure is then carried out. In some implementations, if accurate alignment between the wafer and a lithography mask cannot be implemented, a measurement structure for an overlay between the wafer and the lithography mask may show a spiral map 105 pattern.

Temperature control is not implemented at the interface 103 in some implementations, and wafers 100 may be easily affected by a baking unit \textcircled{1}, and an external environment of a factory and an internal environment of the interface \textcircled{2}, which result in that the wafers will enter the TSU with different temperatures at the interface 103. If temperature control time in the TSU is not enough, stress of a wafer is not released in time, and deformation of the wafer may affect authenticity and stability of an overlay during alignment of the lithography machine, which may even exceed product specifications, so that the wafer needs to be reworked, which extends the process and reduces the production line capacity. If the temperature control time in the TSU is too long, the production capacity of the lithography machine is reduced.

Based on problems in some implementations, the embodiments of the disclosure provide a temperature control apparatus and a temperature control method. Because the temperature control apparatus provided by the embodiments of the disclosure is located at an interface between a coating and developing machine and a lithography machine, so that a wafer at the interface between the coating and developing machine and the lithography machine has an appropriate temperature, thus temperature control time for the wafer in a TSU is reduced, and the production capacity of the lithography machine is improved.

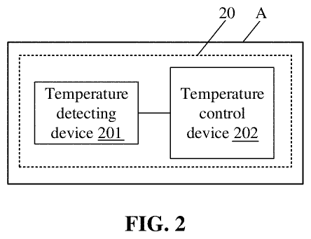

FIG. 2 to FIG. 8 are optional schematic structure diagrams of a temperature control apparatus provided by the embodiments of the disclosure. As illustrated in FIG. 2, a temperature control apparatus 20 is located at an interface A between a coating and developing machine and a lithography machine, and the temperature control apparatus 20 includes a temperature detecting device 201 and a temperature control device 202.

The temperature detecting device 201 is connected to the temperature control device 202. In the embodiments of the disclosure, the connection between the temperature detecting device 201 and the temperature control device 202 may be a wired connection, and may also be a wireless connection. The temperature detecting device 201 is configured to detect actual temperature at the interface A between the coating and developing machine and the lithography machine in real time. The temperature control device 202 is configured to control the actual temperature at the interface A between the coating and developing machine and the lithography machine to reach a target temperature when the actual temperature is not equal to the target temperature.

In some embodiments, the actual temperature includes an ambient temperature at the interface A and a surface temperature of a wafer B located inside the interface A. Correspondingly, the temperature detecting device 201 is configured to detect the ambient temperature and the surface temperature. The temperature control device 202 is configured to control both the ambient temperature and the surface temperature to reach the target temperature.

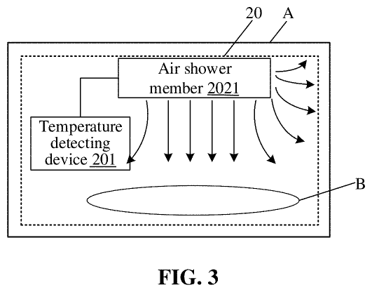

In some embodiments, as illustrated in FIG. 3, a temperature control apparatus 20 is located at an interface A between a coating and developing machine and a lithography machine. The temperature control 20 includes a temperature detecting device 201 and a temperature control device. The temperature control device includes an air shower member 2021. The air shower member 2021 is located at the top inside the interface A. The air shower member 2021 is at least configured to control the ambient temperature at the interface A to reach the target temperature. In other embodiments, the air shower member 2021 is further configured to control a surface temperature of a wafer B located inside the interface A between the coating and developing machine and the lithography machine to reach the target temperature.

In the embodiments of the disclosure, the air shower member 2021 is at least configured to input cold air to the inside of the interface A, to achieve the purpose of cooling the inside of the interface A.

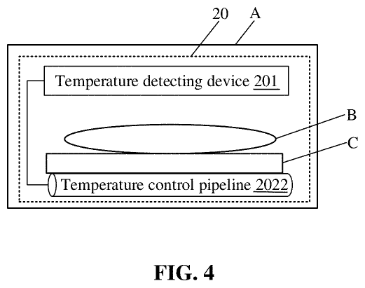

In some embodiments, as illustrated in FIG. 4, a temperature control apparatus 20 is located at an interface A between a coating and developing machine and a lithography machine. The temperature control apparatus 20 includes a temperature detecting device 201 and a temperature control device. The temperature control device includes a temperature control pipeline 2022. The temperature control pipeline 2022 is filled with temperature control liquid or temperature control gas. The temperature control pipeline 2022 is at least in contact with a carrier C of a wafer B, and the temperature control pipeline 2022 is configured to control a surface temperature of the wafer B to reach the target temperature. In other embodiments, the temperature control pipeline 2022 is further configured to control an ambient temperature of the interface to reach the target temperature.

Here, the temperature control liquid may be water, for example, cold water, hot water, liquid nitrogen or other liquid. The temperature control gas may be compressed air or other gas. It should be noted that the temperature control apparatus in the embodiments of the disclosure may be a heating apparatus, or may be a cooling apparatus.

In some embodiments, the temperature control pipeline 2022 is further in contact with a mechanical arm inside the lithography machine (not shown in FIG. 4). The mechanical arm is configured to convey the wafer B from the coating and developing machine into the lithography machine.

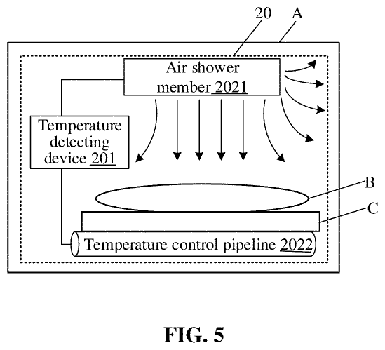

In some embodiments, as illustrated in FIG. 5, a temperature control apparatus 20 is located at an interface A between a coating and developing machine and a lithography machine. The temperature control 20 includes a temperature detecting device 201 and a temperature control device. The temperature control device includes an air shower member 2021 and a temperature control pipeline 2022. The air shower member 2021 is located at the top inside the interface A. The air shower member 2021 is at least configured to control an ambient temperature of the interface to reach the target temperature. The temperature control pipeline 2022 is filled with temperature control liquid or target temperature gas. The temperature control pipeline 2022 is in contact with a carrier C of a wafer B and a mechanical arm inside the lithography machine respectively. The temperature control pipeline 2022 is at least configured to control a surface temperature of the wafer B to reach the target temperature.

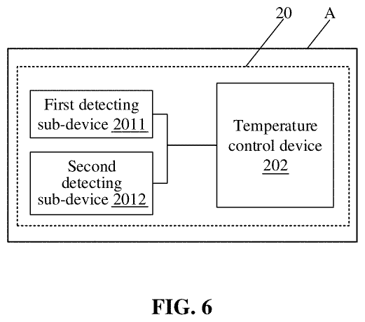

In some embodiments, as illustrated in FIG. 6, a temperature control apparatus 20 is located at an interface A between a coating and developing machine and a lithography machine. The temperature control apparatus 20 includes a temperature detecting device and a temperature control device 202. The temperature detecting device includes a first detecting sub-device 2011 and a second detecting sub-device 2012. The first detecting sub-device 2011 is configured to detect an ambient temperature of the interface A. The second detecting sub-device 2012 is configured to detect a surface temperature of a wafer B located inside the interface A.

Here, the first detecting sub-device and the second detecting sub-device both may be a temperature sensor or a temperature measuring instrument.

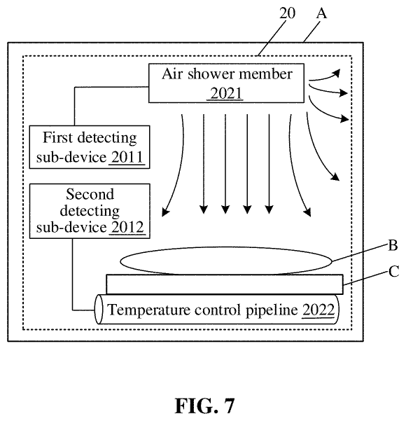

In some embodiments, as illustrated in FIG. 7, a temperature control apparatus 20 is located at an interface A between a coating and developing machine and a lithography machine. The temperature control apparatus 20 includes a temperature detecting device and a temperature control device. The temperature detecting device includes a first detecting sub-device 2011 and a second detecting sub-device 2012. The first detecting sub-device 2011 is configured to detect an ambient temperature of the interface A. The second detecting sub-device 2012 is configured to detect a surface temperature of a wafer B located inside the interface A. The temperature control device includes an air shower member 2021 and a temperature control pipeline 2022. The air shower member 2021 is located at the top inside the interface. The air shower member 2021 is at least configured to control the ambient temperature of the interface A to reach a target temperature. The temperature control pipeline 2022 is filled with temperature control liquid or temperature control gas. The temperature control pipeline 2022 is in contact with a carrier C of the wafer B and a mechanical arm in the lithography machine respectively. The temperature control pipeline 2022 is at least configured to control the surface temperature of the wafer B to reach the target temperature. The mechanical arm is configured to convey the wafer B from the coating and developing machine into the lithography machine.

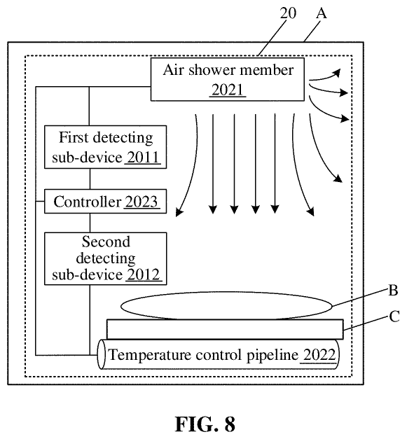

In some embodiments, as illustrated in FIG. 8, a temperature control apparatus 20 is located at an interface A between a coating and developing machine and a lithography machine. The temperature control apparatus 20 includes a temperature detecting device and a temperature control device. The temperature detecting device includes a first detecting sub-device 2011 and a second detecting sub-device 2012. The first detecting sub-device 2011 is configured to detect an ambient temperature of the interface A. The second detecting sub-device 2012 is configured to detect a surface temperature of a wafer B located inside the interface A. The temperature control device includes an air shower member 2021, a temperature control pipeline 2022 and a controller 2023.

In some embodiments, the controller 2023 is connected to the first detecting sub-device 2011 and the air shower member 2021 respectively. The controller 2023 is configured to control the air shower member 2021 to operate when the ambient temperature detected by the first detecting sub-device 2011 is not equal to a target temperature, so as to enable the ambient temperature at the interface to reach the target temperature.

In some embodiments, the controller 2023 is connected to the second detecting sub-device 2012 and the temperature control pipeline 2022 respectively. The controller 2023 is configured to at least control the temperature control pipeline 2022 to operate when the surface temperature detected by the second detecting sub-device 2012 is not equal to the target temperature, so as to enable the surface temperature of the wafer to reach the target temperature.

With continuing reference to FIG. 8, in the embodiments of the disclosure, a controller 2023 is connected to a first detecting sub-device 2011, a second detecting sub-device 2012, an air shower member 2021 and a temperature control pipeline 2022 respectively. The controller 2023 is configured to control the air shower member 2021 or control the air shower member 2021 and the temperature control pipeline 2022 to operate when an ambient temperature detected by the first detecting sub-device 2011 is not equal to a target temperature, so as to enable the ambient temperature at an interface to reach the target temperature. The controller 2023 is further configured to control the temperature control pipeline 2022 or control the air shower member 2021 and the temperature control pipeline 2022 to operate when a surface temperature detected by the second detecting sub-device 2012 is not equal to the target temperature, so as to enable the surface temperature of the wafer B to reach the target temperature.

In the embodiments of the disclosure, when the coating and developing machine and the lithography machine are heated due to a factory environment outside a machine and hot air of a baking unit inside the machine, the temperature is monitored and reduced in time by the temperature control apparatus provided by the embodiments of the disclosure, so that instability of the temperature of a wafer at the interface is reduced, and thus required temperature control time after entering a temperature stable unit (TSU) of the lithography machine is reduced. In this way, it is ensured that stress of the wafer is released in time, and authenticity and stability of an overlay during wafer alignment are improved. Further, by reducing temperature control time of a TSU, process time for each wafer is reduced, and the production capacity of the machine is improved.

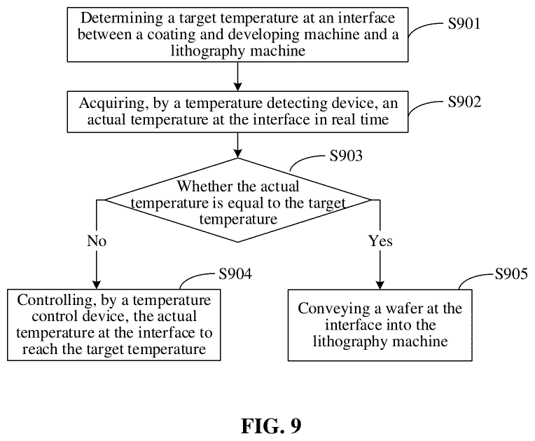

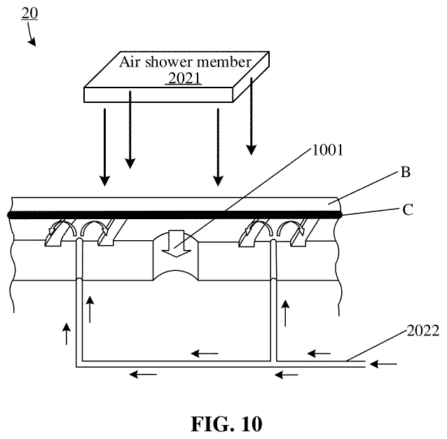

In addition, the embodiments of the disclosure further provide a temperature control method. FIG. 9 is an optional schematic flowchart of a temperature control method provided by the embodiments of the disclosure. FIG. 10 is an optional schematic structure diagram of a temperature control apparatus provided by embodiments of the disclosure. The temperature control method provided by the embodiments of the disclosure is applied to the temperature control apparatus in FIG. 10. As illustrated in FIG. 10, the temperature control apparatus 20 includes a temperature detecting device (not shown in the figure) and a temperature control device. The temperature control apparatus 20 is located at an interface between a coating and developing machine and a lithography machine.

Before the temperature control method in the embodiments of the disclosure is implemented, experiments of Design of Experiments (DOE) under different iCPL temperatures and TSU temperatures are first implemented. Table 1 below shows experiment results of the DOE experiments. From the experiment results, when the iCPL and the TSU have different temperature requirements and a set temperature at an interface is controlled under different conditions, temperature control time of the TSU is different. Under the condition that the iCPL temperature is 22.1° C. and the TSU temperature is 22.2° C., by monitoring the set temperature at the interface of 22° C., the TSU time can be reduced to 11 seconds when a wafer processing is stable and safe. As such, the production capacity of the lithography machine is greatly improved.

TABLE 1
temperature control time corresponding to different set temperatures at an interface

| | Ambient | | | | |
|---|---|---|---|---|---|
| Set | temperature | | | | |
| temperature | of a coating | | Temperature | | Temperature |
| at an | and developing | iCPL | of a mechanical | TSU | control |
| interface/° C. | machine/° C. | temperature/° C. | arm/° C. | temperature/° C. | time/seconds |
| 21 | 23 | 21.2 | 21.6 | 22.2 | 18 |
| 21.5 | 23 | 21.7 | 21.9 | 22.2 | 13 |
| 21.8 | 23 | 21.9 | 21.9 | 22.2 | 10 |
| 21.9 | 23 | 22 | 22.1 | 22.2 | 10 |
| 22 | 23 | 22.1 | 22.2 | 22.2 | 11 |

As illustrated in FIG. 9, the temperature control method provided by the embodiments of the disclosure includes the following step.

At S901, a target temperature at an interface between a coating and developing machine and a lithography machine is determined.

In the embodiments of the disclosure, the target temperature is a control temperature at the interface between the coating and developing machine and the lithography machine, at which a stress effect of a wafer is smallest and temperature control time is shortest, when the wafer enters the lithography machine from the coating and developing machine.

In some embodiments, S901 is formed by the following steps.

At S9011, a first preset temperature of the coating and developing machine and a second preset temperature of the lithography machine are acquired.

The first preset temperature is the control temperature required by the coating and developing machine (i.e., iCPL temperature) within a current factory. The second preset temperature is the control temperature required by the lithography machine (i.e., TSU temperature) within the current factory.

At S9012, according to the first preset temperature and different set temperatures at the interface, a corresponding stability time set is determined when the temperature of a wafer inside the lithography machine reaches the second preset temperature.

In the embodiments of the disclosure, the set temperatures are preset temperatures reached at the interface after a series of controls. The set temperatures may be a temperature set having a preset gradient. According to the first preset temperature and each set temperature, the corresponding temperature time when the temperature of wafer within the lithography machine reaches the second preset temperature can be determined, and thus the stability time set corresponding to each set temperature can be obtained.

At S9013, a set temperature corresponding to a minimum stability time in the stability time set is determined as the target temperature, where an overlay of the wafer satisfies requirements at the target temperature.

At S902, an actual temperature at the interface is acquired by the temperature detecting device in real time.

In some embodiments, the actual temperature includes an ambient temperature at the interface and a surface temperature of the wafer located inside the interface. The temperature detecting device includes a first detecting sub-device and a second detecting sub-device. Here, the first detecting sub-device and the second detecting sub-device may be a temperature sensor or a temperature measuring instrument. S902 is implemented by the following steps.

At S9021, the ambient temperature is acquired by the first detecting sub-device in real time.

At S9022, the surface temperature is acquired by the second detecting sub-device in real time.

In the embodiments of the disclosure, the processes of acquiring the ambient temperature and acquiring the surface temperature of the wafer located inside the interface may be performed simultaneously or asynchronously. The two processes do not have any sequential relationship.

At S903, whether the actual temperature is equal to the target temperature is determined.

In some embodiments, determining whether the actual temperature is equal to the temperature includes the following two determining processes. One is determining whether the ambient temperature is equal to the target temperature. The second is determining whether the surface temperature is equal to the target temperature. In some embodiments, when the ambient temperature and/or the surface temperature are/is not equal to the target temperature, S904 is executed, and when the ambient temperature and the surface temperature each are equal to the target temperature, S905 is executed.

At S904, the actual temperature at the interface is controlled by the temperature control device to reach the target temperature.

In some embodiments, the temperature control device at least includes an air shower member 2021, and S904 at least includes: controlling, by the air shower member, the ambient temperature at the interface to reach the target temperature.

In some embodiments, the temperature control device further includes a temperature control pipeline 2022, and S904 further includes: controlling, by the temperature control pipeline, the surface temperature of the wafer located inside the interface to reach the target temperature.

In the embodiments of the disclosure, the temperature control device includes the air shower member 2021 and the temperature control pipeline 2022, and S904 includes: controlling, by the air shower member, the ambient temperature at the interface to reach the target temperature, and controlling, by the temperature control pipeline, the surface temperature of the wafer located inside the interface to reach the target temperature.

At S905, the wafer at the interface is conveyed into the lithography machine.

In the embodiments of the disclosure, when the actual temperature detected at the interface is equal to the target temperature, there is no need to further use the temperature control apparatus provided by the embodiments of the disclosure to control the surface temperature of the wafer located at the interface and the ambient temperature at the interface, and the wafer can be directly conveyed to the inside of the lithography machine for undergoing a subsequent pre-alignment step.

In some embodiments, the temperature control device further includes a controller (not shown in FIG. 10). The temperature control method further includes: controlling, at least by the controller, the air shower member to operate when the ambient temperature is not equal to the target temperature, so as to enable the ambient temperature to reach the target temperature; or controlling, at least by the controller, the temperature control pipeline to operate when the surface temperature is not equal to the target temperature, so as to enable the surface temperature to reach the target temperature.

In the embodiments of the disclosure, DOE experiments are first developed according to a required iCPL temperature (corresponding to the first preset temperature above) and a required TSU temperature (corresponding to the second preset temperature above) in the current factory, the corresponding relationship between TSU time (corresponding to each stability time in the stability time set above) and a temperature at the interface (corresponding to the set temperature above) is tested, and thus an optimal temperature at the interface (corresponding to the target temperature above) is obtained. Second, by taking temperature monitoring at the interface of the coating and developing machine (track) and the lithography machine (scanner) as a basis, a cooling apparatus, such as the air shower member and the temperature control pipeline, is additionally provided on a wafer conveying apparatus (corresponding to a carrier of the wafer above) or a load robot (corresponding to a mechanical arm inside the lithography machine above) in the interface path, the environment of the wafer at the interface is cooled by an air shower mode, and cyclic cooling is performed below the wafer conveying apparatus/wafer load robot by adding a water cooling pipeline, thereby constituting a platform having cooling and temperature control effects. When the temperature at the interface exceeds the target temperature, the temperature is reduced to the target temperature in time, so that the TSU time is reduced, line stability is achieved, and the productivity of improved.

With continuing reference to FIG. 10, a vacuum suctioning cup 1001 is provided at the center of a carrier C below a chuck for carrying the wafer B and the load robot at the interface between the coating and developing machine and the lithography machine, so as to fix the wafer. The temperature control pipeline 2022 is provided below the carrier C, and compressed gas or cold water is introduced in the temperature control pipeline 2022 along a direction shown by an arrow in FIG. 10, so as to cool the carrier C to achieve a temperature control effect. Moreover, the air shower member 2021 is additionally provided above the interface, to continuously perform temperature control on the environment of the interface, so that it is ensured that a temperature condition (i.e., the target temperature) is reached at the interface.

The temperature control method in the embodiments of the disclosure is similar to the temperature control apparatus in the embodiments above. For the technical features which are not disclosed in detail in the embodiments of the disclosure, please refer to the foregoing embodiments for understanding, and details are not described herein again.

According to the temperature control method provided by the embodiments of the disclosure, a wafer at an interface between a coating and developing machine and a lithography machine has an appropriate temperature, thus temperature control time for the wafer in a TSU is reduced, and the production capacity of the lithography machine is improved.

The embodiments of the disclosure provide a temperature control apparatus and a temperature control method. The temperature control apparatus is located at an interface between a coating and developing machine and a lithography machine, and includes a temperature detecting device and a temperature control device. The temperature detecting device is connected to the temperature control device and configured to detect the actual temperature at the interface in real time. The temperature control device is configured to control the actual temperature at the interface to reach a target temperature when the actual temperature is not equal to the target temperature. Because the temperature control apparatus provided by the embodiments of the disclosure is located at the interface between the coating and developing machine and the lithography machine, a wafer at the interface between the coating and developing machine and the lithography machine has an appropriate temperature, thus temperature control time for the wafer in a TSU is reduced, and the production capacity of the lithography machine is improved.

In the several embodiments provided in the disclosure, it should be understood that the disclosed apparatus and method may be implemented in a non-target way. The described apparatus embodiments are merely exemplary. For example, the division of units is merely division in logical functions and may be realized in other ways in actual implementation. For example, multiple units or components may be combined, or integrated into another system, or some features may be omitted or not implemented. Furthermore, the coupling or direct coupling among the components illustrated or discussed herein may be implemented.

Features disclosed in several method or device embodiments provided in the disclosure may be combined arbitrarily to form a new method or device embodiment without conflict.

The above are merely some implementations of embodiments of the disclosure, but the scope of protection of the embodiments of the disclosure is not limited thereto. Any modification or replacement easily made by those skilled in the art within the technical scope disclosed by the embodiments of the disclosure shall fall within the scope of protection of the embodiments of the disclosure. Therefore, the scope of protection of the disclosure shall be subject to the scope of protection of the claims.

What is claimed is:

1. A temperature control apparatus, located at an interface between a coating and developing machine and a lithography machine, and comprising a temperature detecting device and a temperature control device, wherein
the temperature detecting device is connected to the temperature control device;
the temperature detecting device is configured to detect an actual temperature at the interface in real time; and
the temperature control device is configured to control the actual temperature at the interface to reach a target temperature when the actual temperature is not equal to the target temperature.

2. The temperature control apparatus of claim 1, wherein the actual temperature comprises an ambient temperature at the interface and a surface temperature of a wafer located inside the interface;
the temperature detecting device is configured to detect the ambient temperature and the surface temperature; and
the temperature control device is configured to control both the ambient temperature and the surface temperature to reach the target temperature.

3. The temperature control apparatus of claim 2, wherein the temperature control device at least comprises an air shower member; and
the air shower member is located at the top inside the interface, and the air shower member is at least configured to control the ambient temperature at the interface to reach the target temperature.

4. The temperature control apparatus of claim 3, wherein the temperature control device further comprises a temperature control pipeline filled with a temperature control liquid or a temperature control gas; and
the temperature control pipeline is at least in contact with a carrier of the wafer, and the temperature control pipeline is at least configured to control the surface temperature of the wafer to reach the target temperature.

5. The temperature control apparatus of claim 4, wherein the temperature control pipeline is further in contact with a mechanical arm inside the lithography machine; and
the mechanical arm is configured to convey the wafer from the coating and developing machine into the lithography machine.

6. The temperature control apparatus of claim 4, wherein the temperature control liquid comprises water, and the temperature control gas comprises compressed gas.

7. The temperature control apparatus of claim 3, wherein the temperature detecting device comprises a first detecting sub-device and a second detecting sub-device, and
wherein the first detecting sub-device is configured to detect the ambient temperature at the interface; and
the second detecting sub-device is configured to detect the surface temperature of the wafer located inside the interface.

8. The temperature control apparatus of claim 7, wherein the temperature control device further comprises a controller; the controller is at least connected to the first detecting sub-device and the air shower member, respectively; and
the controller is configured to at least control the air shower member to operate when the ambient temperature detected by the first detecting sub-device is not equal to the target temperature, so as to enable the ambient temperature at the interface to reach the target temperature.

9. The temperature control apparatus of claim 8, wherein the controller is further connected to the second detecting sub-device and the temperature control pipeline, respectively; and
the controller is further configured to at least control the temperature control pipeline to operate when the surface temperature detected by the second detecting sub-device is not equal to the target temperature, so as to enable the surface temperature of the wafer to reach the target temperature.

10. A temperature control method, applied to the temperature control apparatus of claim 1, wherein the temperature control apparatus comprises a temperature detecting device and a temperature control device, and the method comprises:
determining the target temperature at the interface between the coating and developing machine and the lithography machine;
acquiring, by the temperature detecting device, the actual temperature at the interface in real time; and
controlling, by the temperature control device, the actual temperature at the interface to reach the target temperature when the actual temperature is not equal to the target temperature.

11. The temperature control method of claim 10, wherein said determining the target temperature at the interface between the coating and developing machine and the lithography machine comprises:
acquiring a first preset temperature of the coating and developing machine and a second preset temperature of the lithography machine;
determining, according to the first preset temperature and different set temperatures at the interface, a corresponding stability time set when the temperature of a wafer inside the lithography machine reaches the second preset temperature; and
determining a set temperature corresponding to a minimum stability time in the stability time set as the target temperature, wherein an overlay of the wafer satisfies requirements at the target temperature.

12. The temperature control method of claim 11, wherein the actual temperature comprises an ambient temperature at the interface and a surface temperature of the wafer located inside the interface; the temperature detecting device comprises a first detecting sub-device and a second detecting sub-device; and
said acquiring, by the temperature detecting device, the actual temperature at the interface in real time comprises:
acquiring, by the first detecting sub-device, the ambient temperature in real time; and
acquiring, by the second detecting sub-device, the surface temperature in real time.

13. The temperature control method of claim 12, wherein the temperature control device at least comprises an air shower member; and
said controlling, by the temperature control device, the actual temperature at the interface to reach the target temperature at least comprises:
controlling, by the air shower member, the ambient temperature at the interface to reach the target temperature.

14. The temperature control method of claim 13, wherein the temperature control device further comprises a temperature control pipeline; and
said controlling, by the temperature control device, the actual temperature at the interface to reach the target temperature further comprises:
controlling, by the temperature control pipeline, the surface temperature of the wafer located inside the interface to reach the target temperature.

15. The temperature control method of claim 14, wherein the temperature control device further comprises a controller, and the method further comprises:
controlling, at least by the controller, the air shower member to operate when the ambient temperature is not equal to the target temperature, so as to enable the ambient temperature to reach the target temperature; or,
controlling, at least by the controller, the temperature control pipeline to operate when the surface temperature is not equal to the target temperature, so as to enable the surface temperature to reach the target temperature.
